(19) United States
(12) Patent Application Publication
(10) Pub. No.: US 2010/0190463 A1
(43) Pub. Date: Jul. 29, 2010

(54) FREQUENCY DIVIDER WITH AN AC-COUPLING ELEMENT ON ITS FEEDBACK PATH

(75) Inventor: Herbert Knapp, Munich (DE)

Correspondence Address: ESCHWEILER & ASSOCIATES LLC, 629 EUCLID AVENUE, SUITE 1000, NATIONAL CITY BUILDING, CLEVELAND, OH, 44114, US

(73) Assignee: Infineon Technologies AG, Neubiberg (DE)

(21) Appl. No.: 12/361,909

(22) Filed: Jan. 29, 2009

(51) Int. Cl. H04B 1/06; H03B 19/00

(52) U.S. Cl. 455/313; 327/118

(57) ABSTRACT

One embodiment relates to a frequency divider. The frequency divider includes an active mixer having a first mixer input, a second mixer input, and a mixer output. The first mixer input is adapted to receive an input signal having an input frequency, and the mixer output is adapted to provide a mixed signal based on the input signal. The frequency divider also includes an amplification element having an amplification input and an amplification output. The amplification input is adapted to receive the mixed signal and the amplification output is adapted to provide an amplification output signal having an output frequency. A feedback path, which includes an alternating current (AC) coupling element, couples the amplification output to the second mixer input. Other systems and methods are also disclosed.

### FIELD OF DISCLOSURE

The present disclosure relates generally to methods and systems related to frequency dividers, and more particularly to radio frequency (RF) frequency dividers.

### BACKGROUND

Frequency dividers are used in many applications to reduce the frequency of an input signal to make it more suitable for processing. Although it is easy to construct frequency dividers which are reliable at relatively low frequencies, for example by using flip-flops, it becomes much more challenging to design frequency dividers that are reliable at relatively high frequencies.

State-of-the art frequency dividers that are capable of handing relatively high frequencies suffer from a shortcoming in that they require a relatively high rail-to-rail (e.g., VCC to VEE) voltage. This relatively high rail-to-rail voltage can cause problems. For example, high voltages, particularly when used at high switching frequencies, give rise to high power densities for integrated circuits. These high power densities, somewhat like a stovetop burner, cause an integrated circuit to heat up. If high power densities remain unchecked, they can destroy the integrated circuit and/or the electronic device on which the integrated circuit is included.

Several different approaches can be used, singly or in combination, to limit heating due to high-power densities. In one approach, cooling fans, heat sinks, and the like can be used to attempt to pull heat from the integrated circuit to cool it. Although these components are often somewhat effective, they create additional expense for the integrated circuit module and also increase the size of the integrated circuit module. Therefore, these types of cooling components are less than ideal. Consequently, improved frequency dividers that can operate effectively at high frequencies and low power densities are needed.

### SUMMARY

The following presents a simplified summary. This summary is not an extensive overview, and is not intended to identify key or critical elements. Rather, the primary purpose of the summary is to present some concepts in a simplified form as a prelude to the more detailed description that is presented later.

One embodiment relates to a frequency divider. The frequency divider includes an active mixer having a first mixer input, a second mixer input, and a mixer output. The first mixer input is adapted to receive an input signal having an input frequency, and the mixer output is adapted to provide a mixed signal based on the input signal. The frequency divider also includes an amplification element having an amplification input and an amplification output. The amplification input is adapted to receive the mixed signal and the amplification output is adapted to provide an amplification output signal having an output frequency. A feedback path, which includes an alternating current (AC) coupling element, couples the amplification output to the second mixer input. Other systems and methods are also disclosed.

The following description and annexed drawings set forth in detail certain illustrative aspects and implementations. These are indicative of only a few of the various ways in which the principles disclosed may be employed.

### BRIEF DESCRIPTION OF THE DRAWINGS

FIG. 1 depicts an embodiment of a frequency divider;

FIGS. 2A-2B depict embodiments of frequency dividers having differential inputs and differential outputs and which include two emitter follower stages;

FIGS. 3A-3B depict other embodiments of frequency dividers having differential inputs and differential outputs and which include three emitter follower stages;

FIG. 4 depicts a graphical plot that shows the frequency response of various embodiments as a function of frequency;

FIG. 5 depicts another embodiment of a frequency divider having an active mixer that includes a trans-impedance stage; and

FIG. 6 shows a flow chart illustrating a method in accordance with some aspects of this disclosure.

### DETAILED DESCRIPTION

One or more implementations will now be described with reference to the attached drawings, wherein like reference numerals are used to refer to like elements throughout. It will be appreciated that nothing in this specification is admitted as prior art.

As the inventors have appreciated, in comparison to using cooling fans or other cooling components to limit heating of a frequency divider integrated circuit, a better solution is to reduce the rail-to-rail voltage at which the frequency divider can operate. This reduction in rail-to-rail voltage reduces power density, and thereby limits undesirable integrated circuit heating without the expense associated with cooling fans, etc. In addition, reducing the rail-to-rail voltage of the frequency divider has an additional advantage in that it may make the frequency divider more easily compatible with other integrated circuits that use a similar low-voltage supply voltage. For example, a frequency divider can be designed to share a common supply voltage of about 2.7 V or about 3.3 V with CMOS integrated circuits, thereby easing integration of several integrated circuits. In some embodiments of the present disclosure, this voltage reduction is achieved by including an AC-coupling element on a feedback path of the frequency divider. This AC-coupling element allows the frequency divider to operate at lower rail-to-rail voltages than previously achievable.

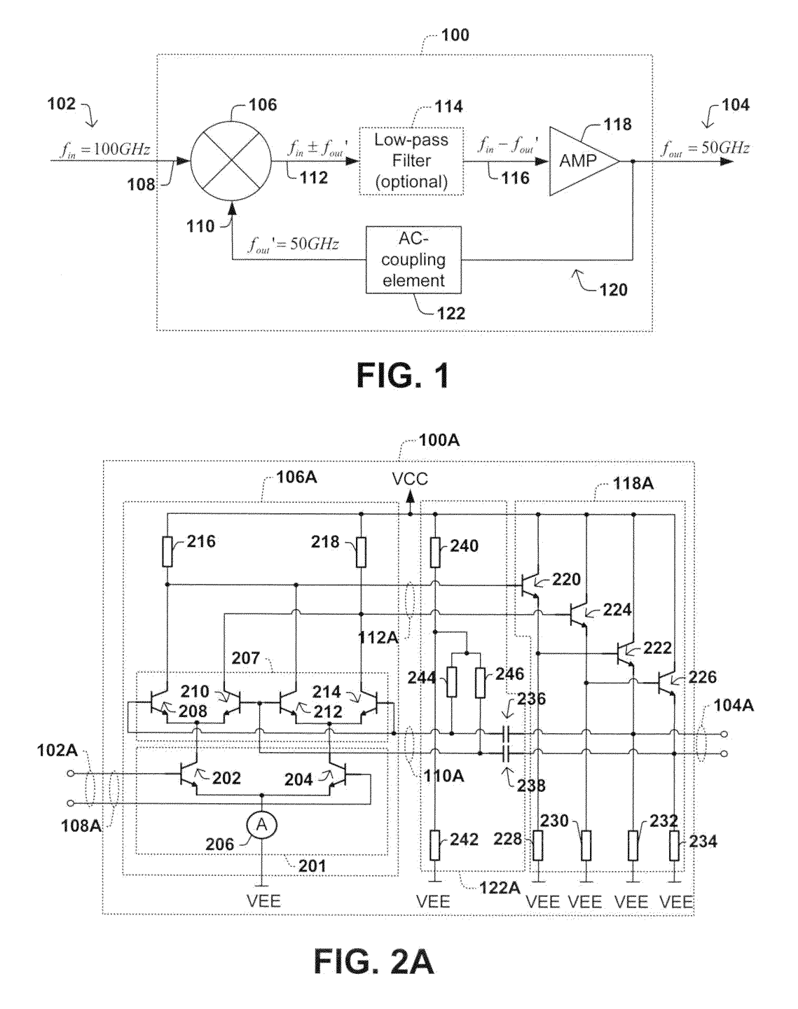

FIG. 1 depicts an embodiment of a dynamic frequency divider 100 having an input 102 and output 104. Between the input 102 and output 104, the dynamic frequency divider 100 includes an active mixer 106 having first and second mixer inputs (108, 110, respectively) and a mixer output 112. The dynamic frequency divider 100 also includes an optional low pass filter 114 and an amplifier 118. A feedback path 120, which includes an AC coupling element 122, couples the output 104 back to the second mixer input 110.

During operation, the dynamic frequency divider 100 receives an input signal having an input frequency on the input 102, and outputs an output signal having an output frequency on the output 104. Typically, the input frequency is an integer multiple of the output frequency—in other words, the frequency divider reduces the input frequency down to some lesser output frequency. For purposes of illustration, one example is discussed below where the input signal has an input frequency of approximately 100 GHz and the output signal has an output frequency of approximately 50 GHz. It will be appreciated that the concept is equally applicable to other frequencies, and is particularly advantageous in the RF range.

More particularly, the input signal, fᵢₙ, is received on the first mixer input 108, and a feedback signal, fₒᵤₜ′, is received on the second mixer input 110. The active mixer 106 multiples these signals together, thereby providing a mixed signal having frequency components at fᵢₙ+fₒᵤₜ′ at fᵢₙ−fₒᵤₜ′. Thus, in this example where the input signal has a frequency of 100 GHz, the mixed signal has frequency components at 50 GHz (i.e., fᵢₙ−fₒᵤₜ′) and 150 GHz (i.e., fᵢₙ+fₒᵤₜ′). Although other harmonics may also be present in the mixed signal, they are omitted in this discussion for simplicity.

The mixed signal on mixer output 112 is optionally received and processed by the low-pass filter 114, which removes unwanted frequency components therefrom. In the illustrated example, the low pass filter 114 removes the 150 GHz frequency component, thereby passing the 50 GHz component (i.e., fᵢₙ−fₒᵤₜ′) to the low pass filter output 116.

The amplifier 118 receives and amplifies the filtered signal, thereby generating the output signal fₒᵤₜ on the output 104. As shown, the output signal fₒᵤₜ has frequency of about 50 GHZ in this example.

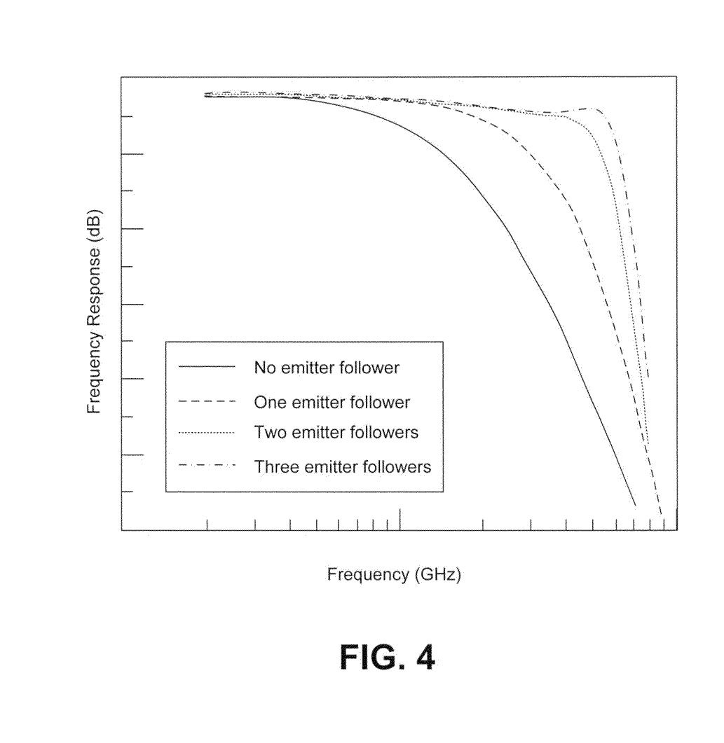

After amplification, the output signal fₒᵤₜ is fed back on the feedback path 120, which includes the AC coupling element 122. The AC-coupling element 122 can be thought of as passing the frequency components from the output signal fₒᵤₜ to the second mixer input 110, and simultaneously blocking the DC voltage in the output signal fₒᵤₜ from reaching the second mixer input 110. In place of the blocked DC voltage, the AC-coupling element generates another DC voltage which is provided to the second mixer input 110. For example, in one embodiment fₒᵤₜ has a 50 GHz frequency with a DC offset of about 0.8 V, while fₒᵤₜ′ also has a 50 GHz frequency but with a DC offset of about 2.5 V. This “blocking” of the DC offset allows the active mixer 106 to use a reduced rail-to-rail voltage relative to previous solutions, and may also improve frequency performance (see FIG. 4 and accompanying discussion below).

In this manner, the frequency divider 100 can cut a frequency of an input signal down to a lower frequency that is more suitable for use in a given system. In addition, because this frequency divider 100 facilitates a reduced rail-to-rail voltage, the frequency divider 100 alleviates some shortcomings of previous solutions. For example, the frequency divider 100 may exhibit a lower power density than previous solutions and may enable easier integration than previously achievable.

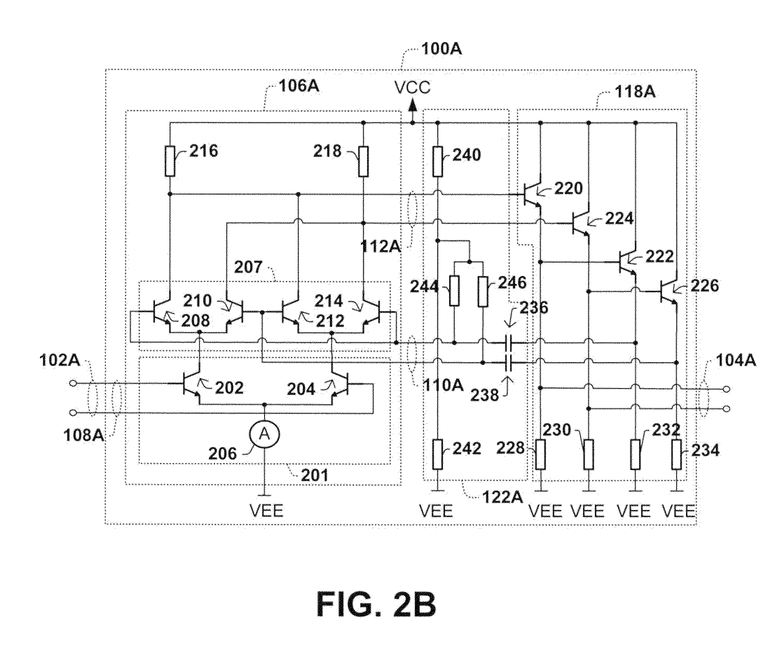

FIG. 2A shows another, more detailed embodiment of a frequency divider 100A that includes a differential input 102A and a differential output 104A. In this embodiment, the active mixer 106 comprises a Gilbert mixer 106A, which tends to remove unwanted frequency components by cancellation. Because of the inherent low-pass characteristics of the Gilbert mixer 106A, this frequency divider 100A does not require a separate low pass filter as shown in the previous embodiment.

The Gilbert mixer 106A includes a first differential mixer input 108A (on which the input signal is received), a second differential mixer input 110A (on which the feedback signal is received), and a differential mixer output 112A (on which a mixed output signal is provided). An RF stage 201 is coupled to the first differential mixer input 108A and includes a pair of RF-stage transistors 202, 204 and a current source 206. A local oscillator (LO) stage 207 is coupled to the second differential mixer input 110A and includes four LO-stage transistors 208, 210, 212, 214. In this example, the transistors in the RF-stage 201 and LO-stage 207 are shown as bipolar junction transistors (BJTs), but they could also be metal oxide semiconductor transistors (MOSFETs) or some other type of transistor. Resistors 216, 218 are also present and separate collectors of the LO stage 207 from the DC supply voltage (VCC).

The differential mixer output 112A is coupled to an amplifier 118A made of a series of emitter follower stages, which collectively act to increase the gain of the circuit. The emitter follower stages may be arranged as “gain boosters” or Darlington pairs, where two transistors are cascaded together to act as a single transistor. Thus, a first emitter follower stage includes a first BJT 220 and first resistor 228; and a second emitter follower stage includes a second BJT 222 and a second resistor 232. The base of the first BJT 220 is coupled to a first leg of the differential mixer output 112A, and a base of the second BJT 222 is coupled to the emitter of the first BJT 220. A third emitter follower stage includes a third BJT 224 and a third resistor 230, and a fourth emitter follower stage includes a fourth BJT 226 and a fourth resistor 234. The base of the third BJT 224 is coupled to a second leg of the differential mixer output 112A, and a base of the fourth BJT 226 is coupled to the emitter of the third BJT 224.

The frequency divider in FIG. 2A includes a feedback path that couples a differential output of the amplifier 118A back to the second differential mixer input 110A. The feedback path includes an AC-coupling element 122A, which includes capacitors that introduce high-pass characteristics in the feedback path as well as resistors that develop a bias voltage for the second differential input 110A of the Gilbert mixer 106A.

More particularly in the AC-coupling element 122A, a first capacitor 236 is in series between a first leg of the differential output 104A and a first leg of the second differential mixer input 110A; and a second capacitor 238 is in series between a second leg of the differential output 104A and a second leg of the second differential mixer input 110A. Typically, the first and second capacitors 236, 238 have equal capacitances. Often, these capacitors do not limit the lower operating frequency limit of the frequency divider because dynamic frequency dividers do not operate down to very low frequencies even when they are DC coupled. Therefore, in some embodiments, the first and second capacitors 236, 238 have a relatively small capacitor value, such as between about 200 fF and about 1 pF, and can be integrated on chip as metal-insulator-metal (MIM) capacitors or using parallel-plate capacitors in the metallization layers of the integrated circuit.

Biasing resistors 240, 242 are arranged to establish a suitable bias voltage to the second differential mixer input 110A. For example, in one embodiment where the VCC supply voltage is approximately 2.7 V, the biasing resistors 240, 242 could be ratioed to provide a bias voltage of about 2.5 V to the points on the feedback path between the capacitors 236, 238 and the second differential mixer input 110A. The other resistors 244, 246 are arranged to deliver the bias to the points and are typically equal in value to one another.

Although FIG. 2A's embodiment shows the legs of the differential output 104A as coupled to the last emitter follower stages (i.e., second and fourth emitter follower stages having transistors 222 and 226, respectively); other arrangements are possible. For example, FIG. 2B shows another embodiment where the differential output 104A is coupled to the first and third emitter follower stages (i.e., emitters of the third and fourth transistors, 220, 224, respectively).

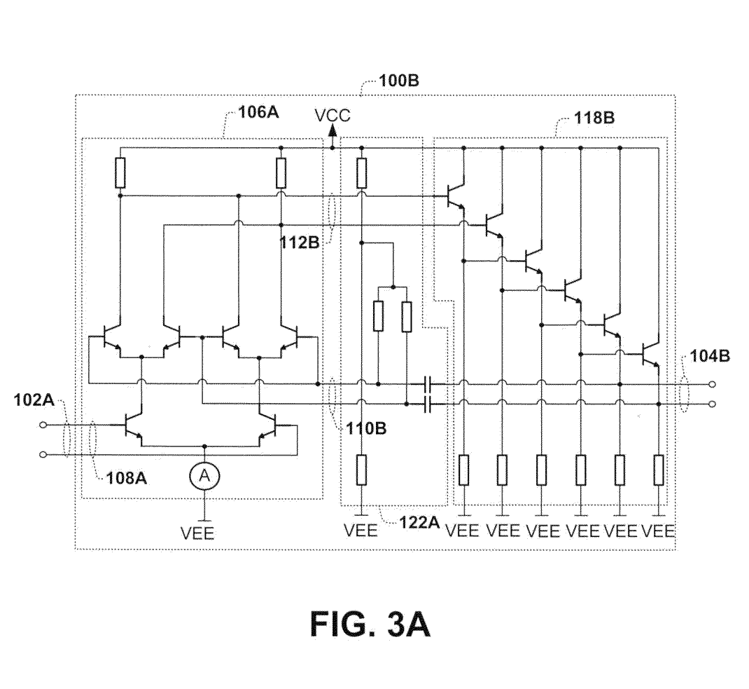

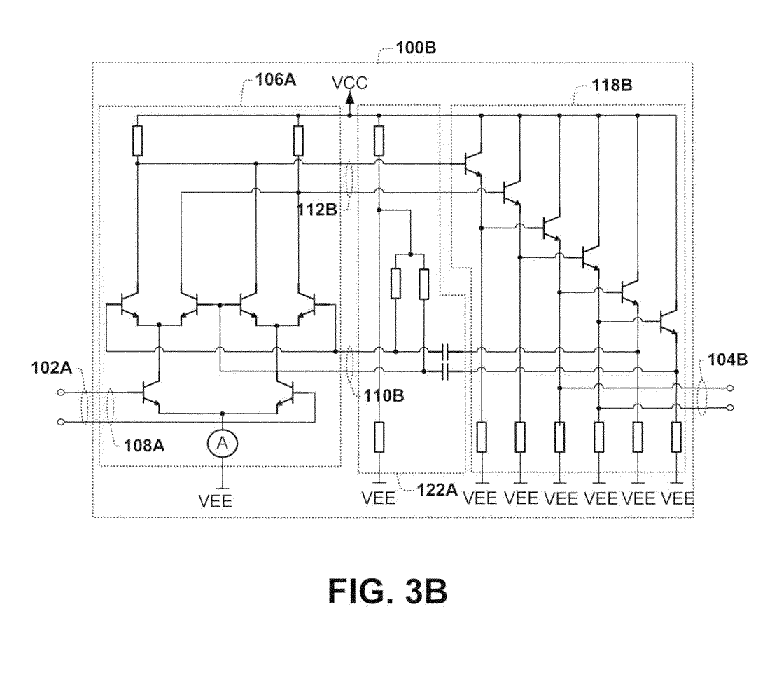

In addition, although FIGS. 2A-2B show frequency dividers 100A where two emitter followers are between each leg of the mixer output 112A and the second mixer input 110A, other implementations may have additional emitter followers—which tends to improve frequency response. For example, FIG. 3A shows another embodiment of a frequency divider 100B that includes three emitter followers between each leg. FIG. 4 shows one example of how gain at high frequency may be improved by increasing the number of emitter followers. Until now, previous solutions have been unable to add additional emitter followers without correspondingly increasing the rail-to-rail voltage necessary for operation. By including the AC-coupling element 122, some aspects of the present application allow the number of emitter followers to be increased while still keeping the rail-to-rail voltage at a relatively low value. As shown by FIG. 4, this provides improved frequency response for frequency dividers. Due to this improvement in frequency response, embodiments with more than two emitter followers provide a significant improvement and are an important contribution of this disclosure, especially because this improvement is believed to have been previously unachievable at reduced rail-to-rail voltages as described herein.

As FIG. 3B shows, the output 104B need not be coupled to the output of the last emitter follower stages as in FIG. 3A, but can also be coupled to the output of another emitter follower stage. For example, in FIG. 3B, the output 104B is coupled to the second emitter follower stages. Thus, it will be appreciated that other numbers of emitter followers are also contemplated as falling within the scope of this disclosure, and the output 104 can be coupled to the output of any output of an emitter follower.

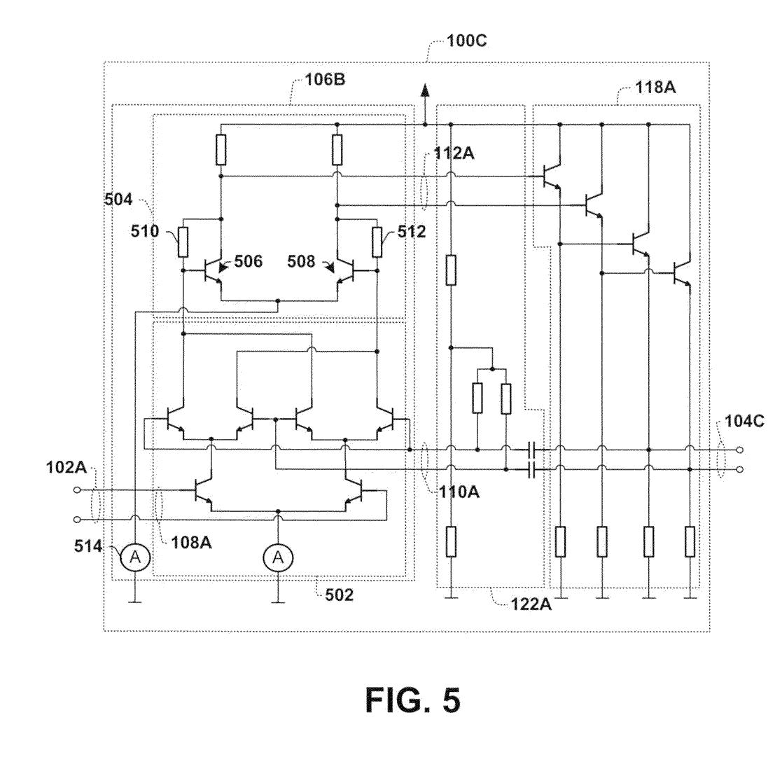

Some aspects of the present disclosure are also applicable to frequency dividers having mixers that include a trans-impedance amplifier. For example, FIG. 5 shows a frequency divider 100C having a mixer 106B that comprises a Gilbert mixer 502 and a trans-impedance stage 504. The trans-impedance stage 504 includes a pair of transistors 506, 508 and a pair of resistors 510, 512. A current source 514 is coupled to the emitters of transistors 506, 508.

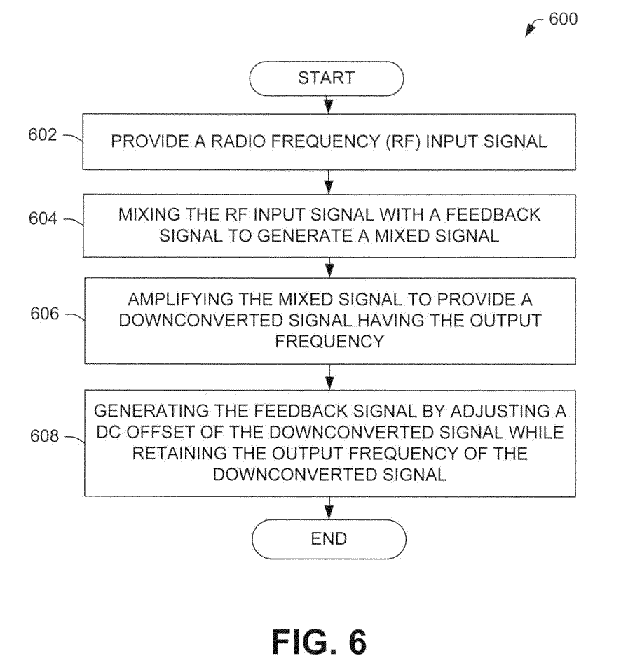

Now that some examples of systems have been discussed, reference is made to FIG. 6, which shows a method 600 in flowchart format. While this method is illustrated and described below as a series of acts or events, the present invention is not limited by the illustrated ordering of such acts or events.

For example, some acts may occur in different orders and/or concurrently with other acts or events apart from those illustrated and/or described herein. In addition, not all illustrated acts may be required. Further, one or more of the acts 25 depicted herein may be carried out in one or more separate acts or phases.

At 602, a radio frequency (RF) input signal is provided. For example, in some embodiments the RF input signal could be provided with a frequency ranging from about 76 GHz to about 81 GHz.

At 604, the RF input signal is mixed with a feedback signal, thereby generating a mixed signal. Because the feedback signal has an output frequency that is a unit fraction of the input frequency, the mixed signal has a frequency component equal to the difference between the input frequency and the output frequency.

At 606, the mixed signal is amplified to provide a downconverted signal having the output frequency. In one embodiment, for example, the downconverted signal is generated to have an output frequency that is one-half of the input frequency, although other unit fractions could also be generated.

At 608, the feedback signal is generated by adjusting a DC offset of the downconverted signal. The feedback signal concurrently retains the output frequency of the downconverted signal.

Although one or more implementations has been illustrated and/or discussed above, alterations and/or modifications may be made to these examples without departing from the spirit and scope of the appended claims.

For example, although some embodiments have been illustrated and described above in which a Gilbert mixer comprised of BJTs, it will be appreciated that other types of transistors, including but not limited to: metal oxide semiconductor field effect transistors (MOSFETs), junction gate field effect transistors (JFETs), insulated gate field effect transistors (IGFETs), insulated gate bipolar transistors (IGBTs); constitute legal equivalents of these BJTs. These transistors may be made of silicon in some embodiments, but may also be made of other materials, including but not limited to: germanium, gallium arsenide, silicon carbide, and others. Similarly, the emitter followers could include transistors other than BJTs, and could be made of silicon or other materials. In typical embodiments, a frequency divider is formed on a single monolithic integrated circuit, but the frequency divider functionality could also be split between several different integrated circuits.

Also, the term “couple” or “couples” is intended to mean either an indirect or direct electrical connection. Thus, if a first device couples to a second device, that connection may be through direct electrical connection, or through an indirect electrical connection via other devices and connections. Although various numeric values are provided herein, these values are just examples and do not limit the scope of the disclosure. Also, all numeric values are approximate.

In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations. In addition, while a particular feature may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A frequency divider, comprising:
an active mixer having a first mixer input, a second mixer input, and a mixer output; the first mixer input adapted to receive an input signal having an input frequency and the mixer output adapted to provide a mixed signal based on the input signal;
an amplification element having an amplification input and an amplification output; the amplification input coupled to the mixer output and adapted to receive the mixed signal, and the amplification output adapted to provide an amplification output signal having an output frequency, the input frequency being an integer multiple of the output frequency; and
a feedback path coupling the amplification output to the second mixer input and comprising an alternating current (AC) coupling element.

2. The frequency divider of claim 1, wherein the input frequency is two times the output frequency.

3. The frequency divider claim 1, where the amplification element comprises:
a first bipolar junction transistor (BJT) comprising: a base coupled to the amplification input, and an emitter; and
a second BJT comprising: a base coupled to the emitter of the first BJT, and an emitter coupled to the amplification output.

4. The frequency divider of claim 1, wherein the AC coupling element comprises:
a capacitor in series between the amplification output and the second mixer input.

5. The frequency divider of claim 4, wherein the AC coupling element further comprises:
a resistor having first and second terminals, the first terminal coupled to a point on the feedback path between the capacitor and the second mixer input, and the second terminal coupled to a DC supply voltage.

6. The frequency divider of claim 5, where the resistor and capacitor are arranged to establish a DC offset voltage at the point, the DC offset at the point differing from another DC offset at the amplification output.

7. The frequency divider of claim 6, where the point and the amplification output are adapted to concurrently establish the same frequency components thereat.

8. The frequency divider of claim 5, where the amplification element comprises:
a first bipolar junction transistor (BJT) comprising: a base coupled to the amplification input, and an emitter; and
a second BJT comprising: a base coupled to the emitter of the first BJT, and an emitter coupled to the amplification output.

9. The frequency divider of claim 1, wherein the active mixer comprises a Gilbert mixer.

10. A frequency divider, comprising:
an active mixer having a first differential mixer input, a second differential mixer input, and a differential mixer output;
an amplification element having a differential amplification input and a differential amplification output, a first leg of the differential amplification input coupled to a first leg of the differential mixer output and a second leg of the differential amplification input coupled to a second leg of the differential mixer output; and
a feedback path coupling the differential amplification output to the second differential mixer input, the feedback path comprising an alternating current (AC) coupling element.

11. The frequency divider of claim 10, wherein the amplification element comprises:
a first bipolar junction transistor (BJT) comprising: a base coupled to the first leg of the differential mixer output, and an emitter;
a second BJT comprising: a base coupled to the emitter of the first BJT, and an emitter coupled to a first leg of the differential amplification output;
a third BJT comprising: a base coupled to the second leg of the differential mixer output, and an emitter; and
a fourth BJT comprising: a base coupled to the emitter of the third BJT, and an emitter coupled to a second leg of the differential amplification output.

12. The frequency divider of claim 10, wherein the AC coupling element comprises:
a first capacitor in series between a first leg of the differential amplification output and a first leg of the second mixer differential input; and
a second capacitor in series between a second leg of the differential amplification output and a second leg of the second mixer differential input.

13. The frequency divider of claim 12, wherein the first and second capacitors are integrated as metal-insulator-metal or parallel plate capacitors in metallization layers of an integrated circuit on which the frequency divider is formed.

14. The frequency divider of claim 12, further comprising:
a first resistor coupled to a first point on the feedback path between the first capacitor and the first leg of the second mixer differential input.

15. The frequency divider of claim 14, further comprising:
a second resistor coupled to a second point on the feedback path between the second capacitor and the second leg of the second mixer differential input.

16. The frequency divider of claim 15, where the first and second resistors are arranged to establish a DC offset voltage at first and second points, the DC offset at the first and second points differing from another DC offset at the amplification output.

17. The frequency divider of claim 10, where the amplification element includes at least three emitter followers coupled between the first amplification input and the differential amplification output.

18. A method of downconverting a radio-frequency (RF) input signal having an input frequency, comprising:
mixing the RF input signal with a feedback signal to generate a mixed signal; the feedback signal having an output frequency that is a unit fraction of the input frequency, and the mixed signal having a frequency component equal to the difference between the input frequency and the output frequency;
amplifying the mixed signal to provide a downconverted signal having the output frequency; and
generating the feedback signal by adjusting a DC offset of the downconverted signal while passing the output frequency of the downconverted signal to the feedback signal.

19. The method of claim 18, wherein the RF input signal has a frequency of approximately 77 GHz.

20. The method of claim 18, wherein the downconverted signal has a frequency that is one-half of the input frequency.

21. A frequency divider, comprising:
mixer means for mixing an input signal and a feedback signal to generate a mixed signal, the input signal having an input frequency;
amplification means for providing a down-converted signal based on the mixed signal, the down-converted signal having an output frequency that is a unit fraction of the input frequency; and
feedback means for generating the feedback signal, the feedback signal having a DC offset that differs from that of the downconverted signal but having the output frequency of the downconverted signal.
